(19) United States
(12) Patent Application Publication
(10) Pub. No.: US 2025/0125238 A1
(43) Pub. Date: Apr. 17, 2025

(54) SEMICONDUCTOR PACKAGE

(71) Applicant: SAMSUNG ELECTRO-MECHANICS CO., LTD., Suwon-si, Gyeonggi-do (KR)

(72) Inventors: Jin Uk LEE, Suwon-si, Gyeonggi-do (KR); Gopal Garg, Suwon-si, Gyeonggi-do (KR)

(73) Assignee: SAMSUNG ELECTRO-MECHANICS CO., LTD., Suwon-si, Gyeonggi-do (KR)

(21) Appl. No.: 18/379,304

(22) Filed: Oct. 12, 2023

(51) Int. Cl. H01L 23/498; H01L 23/00; H01L 25/065; H01L 25/18

(52) U.S. Cl. CPC H01L 23/49822; H01L 23/49838; H01L 24/16; H01L 24/32; H01L 24/73; H01L 25/0657; H01L 25/18; H01L 2224/16225; H01L 2224/32225; H01L 2224/73204; H01L 2225/06541; H01L 2924/1517

(57) ABSTRACT

A semiconductor package includes a first substrate including a first insulating layer and a first wiring layer disposed on or in the first insulating layer; first and second packages disposed on the first substrate, and each including a substrate, a semiconductor chip on the substrate, connection members connecting the substrate to the semiconductor chip, and a SERDES chip embedded in the substrate; 1-1 connection members connecting the first substrate to the first package; and 2-1 connection members connecting the first substrate to the second package. The number of connection members of the first package is greater than the number of 1-1 connection members. The number of connection members of the second package is greater than the number of 2-1 connection members.

### TECHNICAL FIELD

The present disclosure relates to a semiconductor package.

### BACKGROUND

Memory chips such as a high bandwidth memory (HBM) and a multi-chip package including processor chips such as a central processing unit (CPU), a graphics processing unit (GPU), an application specific integrated circuit (ASIC), and a field programmable gate array (FPGA) to process data which has been increased exponentially due to the recent development of artificial intelligence (AI) technology have been used. Also, as the number of CPU and GPU cores in a server product has rapidly increased, die-split technology which may effectively increase the number of cores has been commonly used, and demand for high-density circuits connecting logic semiconductors and memory semiconductors or between logic semiconductors has also rapidly increased, demand for die-to-die interconnections connecting the component has also increased. To design a substrate for performing die-to-die interconnection, a technique for implementing fine circuits may be necessary, and research has been conducted to promote a simplified substrate and a package structure to reduce high-density microcircuits and to increase yield while improving reliability of the connection structure.

### SUMMARY

An aspect of the present disclosure is to provide a semiconductor package which may perform die-to-die interconnection in a package including a semiconductor chip.

Another aspect of the present disclosure is to provide a semiconductor package including a simplified wiring structure in die-to-die interconnection.

Another aspect of the present disclosure is to provide a semiconductor package which may improve reliability.

According to an aspect of the present disclosure, a semiconductor package includes a first substrate including a first insulating layer and a first wiring layer disposed on or in the first insulating layer; a first package disposed on the first substrate, and including a second substrate, a first semiconductor chip disposed on the second substrate, first connection members connecting the second substrate to the first semiconductor chip, and a first SERDES chip embedded in the second substrate; a second package disposed on the first substrate, and including a second semiconductor chip disposed on the third substrate, second connection members connecting the third substrate to the second semiconductor chip, and a second SERDES chip embedded in the third substrate; 1-1 connection members connecting the first substrate to the first package; and 2-1 connection members connecting the first substrate to the second package. The number of first connection members is greater than the number of 1-1 connection members. The number of second connection members is greater than the number of 2-1 connection members.

According to an aspect of the present disclosure, a semiconductor package includes a first substrate comprising a first insulating layer and a first wiring layer disposed on or in the first insulating layer; a first package disposed on the first substrate, and including a second substrate, a first semiconductor chip disposed on the second substrate, a first connection member connecting the second substrate to the first semiconductor chip, and a first SERDES chip embedded in the second substrate; a second package disposed on the first substrate, and including a third substrate, a second semiconductor chip disposed on the third substrate, a second connection member connecting the third substrate to the second semiconductor chip, and a second SERDES chip embedded in the third substrate; a 1-1 connection member connecting the first substrate to the first package; and a 2-1 connection member connecting the first substrate to the second package. The first semiconductor chip and the second semiconductor chip are connected to each other by a path passing through the first SERDES chip, the second substrate, the first substrate, the third substrate, and the second SERDES chip.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a block diagram illustrating an example of an electronic device system;

FIG. 2 is a perspective diagram illustrating an example of an electronic device;

FIG. 3 is a cross-sectional diagram illustrating a semiconductor package according to an embodiment;

FIG. 4 is a cross-sectional diagram illustrating a first package of a semiconductor package according to an embodiment;

FIG. 5 is a cross-sectional diagram illustrating a first package according to another embodiment;

FIG. 6 is a cross-sectional diagram illustrating a semiconductor package according to another embodiment;

FIG. 7 is a cross-sectional diagram illustrating a first package of a semiconductor package according to another embodiment; and

FIG. 8 is a cross-sectional diagram illustrating a first package according to another embodiment.

### DETAILED DESCRIPTION

Hereinafter, embodiments of the present disclosure will be described as follows with reference to the attached drawings.

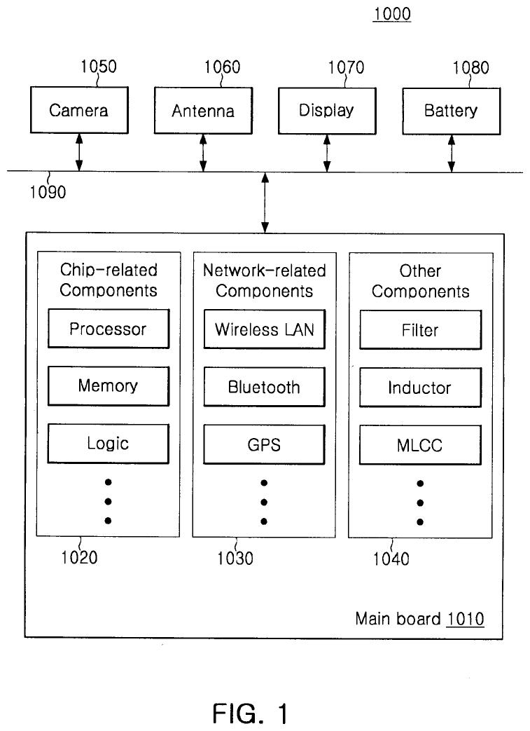

FIG. 1 is a block diagram illustrating an example of an electronic device system.

Referring to FIG. 1, an electronic device 1000 may accommodate a mainboard 1010 therein. The mainboard 1010 may include chip related components 1020, network related components 1030, other components 1040, and the like, physically or electrically connected thereto. These components may be connected to others to be described below to form various signal lines 1090.

The chip related components 1020 may include a memory chip such as a volatile memory (for example, a dynamic random access memory (DRAM)), a non-volatile memory (for example, a read only memory (ROM)), a flash memory, or the like; an application processor chip such as a central processor (for example, a central processing unit (CPU)), a graphics processor (for example, a graphics processing unit (GPU)), a digital signal processor, a cryptographic processor, a microprocessor, a microcontroller, or the like; and a logic chip such as an analog-to-digital (ADC) converter, an application-specific integrated circuit (ASIC), or the like. However, the chip related components 1020 are not limited thereto, and may also include other types of chip related components. Also, the chip related components 1020 may be combined with each other. The chip-related component 1020 may be in the form of a package including the aforementioned chip or electronic component.

The network related components 1030 may include protocols such as wireless fidelity (Wi-Fi) (Institute of Electrical And Electronics Engineers (IEEE) 802.11 family, or the like), worldwide interoperability for microwave access (WiMAX) (IEEE 802.16 family, or the like), IEEE 802.20, long term evolution (LTE), evolution data only (Ev-DO), high speed packet access+ (HSPA+), high speed downlink packet access+ (HSDPA+), high speed uplink packet access+ (HSUPA+), enhanced data GSM environment (EDGE), global system for mobile communications (GSM), global positioning system (GPS), general packet radio service (GPRS), code division multiple access (CDMA), time division multiple access (TDMA), digital enhanced cordless telecommunications (DECT), Bluetooth, 3G, 4G, and 5G protocols, and any other wireless and wired protocols, designated after the abovementioned protocols. However, the network related components 1030 are not limited thereto, but may also include a variety of other wireless or wired standards or protocols. Also, the network related components 1030 may be combined with each other, together with the chip related components 1020 described above.

Other components 1040 may include a high frequency inductor, a ferrite inductor, a power inductor, ferrite beads, a low temperature co-fired ceramic (LTCC), an electromagnetic interference (EMI) filter, a multilayer ceramic capacitor (MLCC), or the like. However, other components 1040 are not limited thereto, but may also include passive components used for various other purposes, or the like. Also, other components 1040 may be combined with each other, together with the chip related components 1020 or the network related components 1030 described above.

Depending on a type of the electronic device 1000, the electronic device 1000 may include other components which may or may not be physically or electrically connected to the mainboard 1010. The other components may include, for example, a camera module 1050, an antenna module 1060, a display device 1070, and a battery 1080. However, the other components are not limited thereto, and may include an audio codec, a video codec, a power amplifier, a compass, an accelerometer, a gyroscope, a speaker, a mass storage unit (for example, a hard disk drive), a compact disk (CD) drive, a digital versatile disk (DVD) drive, or the like. The other components may also include other components used for various purposes depending on a type of electronic device 1000.

The electronic device 1000 may be a smartphone, a personal digital assistant (PDA), a digital video camera, a digital still camera, a network system, a computer, a monitor, a tablet PC, a laptop PC, a netbook PC, a television, a video game machine, a smartwatch, an automotive component, or the like. However, the electronic device 1000 is not limited thereto, and may be any other electronic device for processing data.

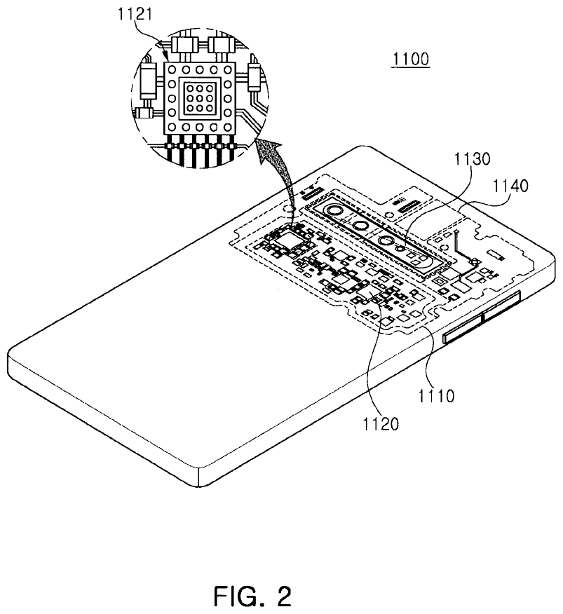

FIG. 2 is a perspective diagram illustrating an example of an electronic device.

Referring to FIG. 2, the electronic device may be implemented as, for example, the smartphone 1100. A motherboard 1110 may be accommodated in a body 1101 of a smartphone 1100, and various electronic components 1120 may be physically or electrically connected to the motherboard 1110. Also, other components which may or may not be physically or electrically connected to the motherboard 1110, such as a camera module 1130, may be accommodated in the body 1101. A portion of the electronic components 1120 may be the chip related components, a component package 1121, for example, but are not limited thereto. The component package 1121 may be in the form of a printed circuit board on which electronic components including active components and/or passive components are surface-mounted. Alternatively, the component package 1121 may be in the form of a printed circuit board in which active components and/or passive components are embedded. The electronic device is not necessarily limited to the smartphone 1100, but may be other electronic devices as described above.

### Semiconductor Package

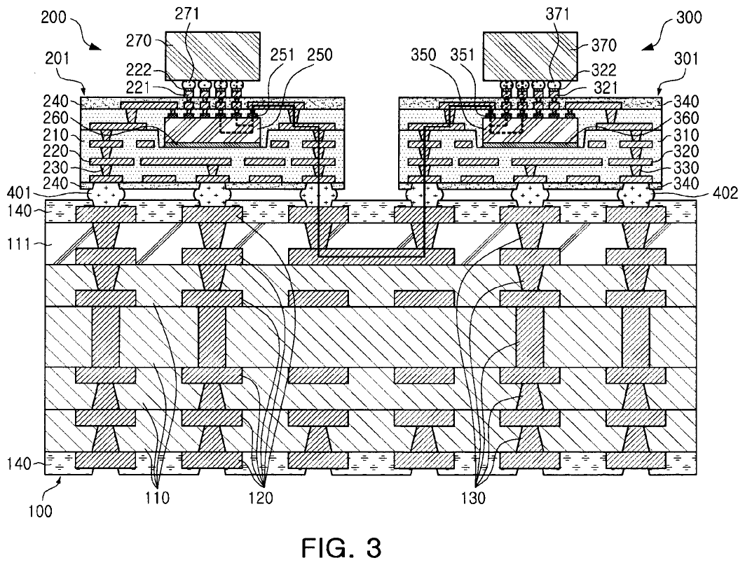

FIG. 3 is a cross-sectional diagram illustrating a semiconductor package according to an embodiment.

Referring to FIG. 3, the semiconductor package according to the embodiment may include a first substrate 100, a first package 200 disposed on the first substrate 100, a second package 300 disposed on the first substrate 100, a 1-1 connection member 401 connecting the first substrate 100 to the first package 200, and a 2-1 connection member 402 connecting the first substrate 100 to the second package 300.

The first substrate 100 may be disposed on a mainboard, may correspond to an intermediate component for mounting the first package 200 and the second package 300, and the first substrate 100 may be configured as a printed circuit board. The first substrate 100 may include a first insulating layer 110, a first wiring layer 120 disposed on or in the first insulating layer 110, and a first via layer 130 penetrating through at least a portion of the first insulating layer 110 to connect the first wiring layers 120 to each other.

The first insulating layer 110 may include a plurality of insulating layers, and each first insulating layer 110 may include an insulating material. The insulating material may include a thermosetting resin such as epoxy resin, a thermoplastic resin such as polyimide, or a material including an inorganic filler, an organic filler, and/or glass fiber (glass fiber, glass cloth, and/or glass fabric) together with the resins. The insulating material may be a photosensitive material and/or a non-photosensitive material. For example, the insulating material of the first insulating layer 110 may be prepreg (PPG) or resin coated copper (RCC) insulating material, but an embodiment thereof is not limited thereto, and the insulating material may be Ajinomoto build-up film (ABF), photoimageable dielectric (PID), FR-4, bismaleimide triazine (BT), and the like. However, an embodiment thereof is not limited thereto, and if desired, other polymer materials having excellent rigidity may be used. The first insulating layer 110 may include an insulating layer corresponding to a core layer. As illustrated in FIG. 3, the first insulating layer 110 may be configured to be symmetrical with respect to the core layer, but an embodiment thereof is not limited thereto, and the first insulating layer 110 may have a coreless structure, not including a core layer.

The first insulating layer 110 may include a 1-1 insulating layer 111 on an uppermost side. The 1-1 insulating layer 111 may include an insulating material. The 1-1 insulating layer 111 may include an insulating material having a signal loss rate lower than those of the other first insulating layers 110. For example, the 1-1 insulating layer 111 may include a material having a dissipation factor (Df) lower than that of the first insulating layer 110, and may include a material having a relatively smaller dielectric constant (Dk), or may include a material having a relatively and a small dissipation factor (Df) relatively small dielectric constant (Dk).

The insulating material of the 1-1 insulating layer 111 may be prepreg (PPG) or resin coated copper (RCC) insulating material, but an embodiment thereof is not limited thereto, and the insulating material may be Ajinomoto build-up film (ABF), photoimageable dielectric (PID), FR-4, bismaleimide triazine (BT), and the like, may have a dissipation factor (Df) value smaller than a dissipation factor (Df) of the first insulating layer 110, and may include liquid crystal polymer (LCP), polytetrafluoroethylene (PTFE), polyphenylene ether (PPE), cycloolefin polymer (COP), and perfluoroalkoxy (PFA), but an embodiment thereof is not limited thereto.

As described later, since a high-speed signal may be transmitted from the first package 200 to the second package 300 through the 1-1 insulating layer 111, by configuring the dissipation factor (Df) of the 1-1 insulating layer 111 to be lower than the dissipation factor (Df) of the first insulating layer 110, a signal loss rate may be reduced. In FIG. 3, the 1-1 insulating layer 111 may be disposed on the uppermost side of the first insulating layer 110 of the first substrate 100, but an embodiment thereof is not limited thereto, and any region in which the first wiring layer 120 may be disposed for a high-speed signal generated in the first package 200 to be transmitted to the second package 300 may be used. Also, in FIG. 3, a single 1-1 insulating layer 111 may be provided, but an embodiment thereof is not limited thereto, and when a signal is transferred from the first package 200 to the second package 300 through a plurality of wiring layers, the 1-1 insulating layer 111 may also include the plurality of 1-1 insulating layers 111. That is, the 1-1 insulating layer 111 may be disposed in any region in which the first wiring layer 120 is disposed such that the high-speed signal generated in the first package 200 is transmitted to the second package 300.

The first wiring layer 120 may include a plurality of wiring layers, and each first wiring layer 120 may include a metal material. As a metal material, copper (Cu), aluminum (Al), silver (Ag), tin (Sn), gold (Au), nickel (Ni), lead (Pb), titanium (Ti), or alloys thereof may be used. Each of the first wiring layers 120 may include an electroless plating layer (or chemical copper) as a seed layer and an electrolytic plating layer (or electrolytic copper) as a plating layer, but an embodiment thereof is not limited thereto. A sputtering layer may be formed instead of chemical copper as the electroless plating layer. If desired, copper foil may be further included. Each of the first wiring layers 120 may perform various functions according to a design of the corresponding layer. For example, a ground pattern, a power pattern, a signal pattern, and the like may be included. Here, the signal pattern may include various signals other than a ground pattern and a power pattern, for example, a data signal. Each of the patterns may include a line pattern, a plane pattern, and/or a pad pattern.

The first via layer 130 may include a plurality of via layers, and each first via layer 130 may include a micro-via. A micro-via may be a filled via for filling a via hole or a conformal via disposed along a wall surface of a via hole. The micro-vias may be arranged in a stacked type and/or a staggered type. Each first via layer 130 may include a metal material. The metal material may include a metal material such as copper (Cu), aluminum (Al), silver (Ag), tin (Sn), gold (Au), nickel (Ni), lead (Pb), titanium (Ti), or alloys thereof. Each of the connection via layers may include an electroless plating layer (or chemical copper) as a seed layer and an electrolytic plating layer (or electrolytic copper) as a plating layer, but an embodiment thereof is not limited thereto. A sputtering layer may be formed instead of chemical copper as the electroless plating layer. The first via layer 130 may perform various functions according to the design of the corresponding layer. For example, a ground via, a power via, a signal via, and the like may be included. Here, the signal vias may include vias for transferring various signals, for example, a data signal, other than a ground via and a power via.

The first wiring layer 120 and the first via layer 130 may be integrated with each other, respectively, but an embodiment thereof is not limited thereto. The first wiring layer 120 and/or the first via layer 130 may be formed by one of a semi-additive process (SAP), a modified semi-additive process (MSAP), tenting (TT) or a subtractive method, but an embodiment thereof is not limited thereto, and any construction method for configuring a circuit on a printed circuit board may be used without limitation.

The first substrate 100 may further include a first solder resist layer 140 on an outermost side. The first solder resist layer 140 may protect the first substrate 100 from an external region and may be disposed on an uppermost side of the first substrate 100 and/or a lowermost side of the first substrate 100. The first solder resist layer 140 may include a thermosetting resin and an inorganic filler dispersed in the thermosetting resin, and may not include glass fibers. The insulating resin may be a photosensitive insulating resin, and the filler may be an inorganic filler and/or an organic filler, but an embodiment thereof is not limited thereto. However, the material of the first solder resist layer 140 is not limited thereto, and if desired, any solder resist material used in the field of printed circuit board, such as other polymer materials may be used without limitation. The first solder resist layer 140 may include an opening, and may perform a function of the pad from which a portion of the first wiring layer 120 may be exposed through the opening and may be connected to the other component.

The number of the first insulating layers 110, the number of the first wiring layers 120 and the number of the first via layers 130 may be varied in embodiments, and the arrangement of the core layer of the first insulating layer 110 may also be varied in embodiments. However, an embodiment thereof is not limited thereto, and the first substrate 100 may be configured to be usable by those skilled in the art of printed circuit boards.

The first package 200 may include a second substrate 201, a first semiconductor chip 270 disposed on the second substrate 201, a first connection member 271 connecting the second substrate 201 to the first semiconductor chip 270, and a first SERDES chip embedded in the second substrate 201.

The first package 200 may be configured as a chip package including the first semiconductor chip 270, and may have a structure in which the first semiconductor chip 270 is mounted on the second substrate 201. The second substrate 201 may be configured as a printed circuit board and may have a fine structure to be connected to the first semiconductor chip 270. The second substrate 201 may include a second insulating layer 210, a second wiring layer 220 disposed on or in the second insulating layer 210, and a second via layer 230 penetrating through at least a portion of the second insulating layer 210 to connect the second wiring layers 220 to each other.

The second insulating layer 210 may include a plurality of insulating layers, and each second insulating layer 210 may include an insulating material. The insulating material may include a thermosetting resin such as epoxy resin, a thermoplastic resin such as polyimide, or a material including an inorganic filler, an organic filler, and/or glass fiber (glass fiber, glass cloth, and/or glass fabric) together with the resins. The insulating material may be a photosensitive material and/or a non-photosensitive material. For example, the insulating material of the first insulating layer 110 may be prepreg (PPG) or resin coated copper (RCC) insulating material, but an embodiment thereof is not limited thereto, and the insulating material may be Ajinomoto build-up film (ABF), photoimageable dielectric (PID), FR-4, bismaleimide triazine (BT), and the like. However, an embodiment thereof is not limited thereto, and if desired, other polymer materials having excellent rigidity may be used. The second insulating layer 210 may include a plurality of second insulating layers 210, and the plurality of second insulating layers 210 may not include the same material, and may include different insulating materials for each layer. For example, in a region connected to the first semiconductor chip 270, the second insulating layer 210 may use a photoimageable dielectric (PID) to form a microcircuit, but an embodiment thereof is not limited thereto.

The second wiring layer 220 may include a plurality of wiring layers, and each second wiring layer 220 may include a metal material. As a metal material, copper (Cu), aluminum (Al), silver (Ag), tin (Sn), gold (Au), nickel (Ni), lead (Pb), titanium (Ti), or alloys thereof may be used. The second wiring layer 220 may each include an electroless plating layer (or chemical copper) as a seed layer and an electrolytic plating layer (or electrolytic copper) as a plating layer, but an embodiment thereof is not limited thereto. A sputtering layer may be formed instead of chemical copper as the electroless plating layer. If desired, copper foil may be further included. The second wiring layer 220 may perform various functions according to the design of each corresponding layer. For example, a ground pattern, a power pattern, a signal pattern, and the like may be included. Here, the signal pattern may include various signals other than a ground pattern and a power pattern, for example, a data signal. Each of these patterns may include a line pattern, a plane pattern, and/or a pad pattern. The second wiring layer 220 disposed on the uppermost side of the second wiring layer 220 may have a structure exposed from the second insulating layer 210 and may further include a surface treatment layer on the exposed surface.

The second via layer 230 may include a plurality of via layers, and each second via layer 230 may include a micro-via. A micro-via may be a filled via for filling a via hole or a conformal via disposed along a wall surface of a via hole. The micro-vias may be arranged in a stacked type and/or a staggered type. Each second via layer 230 may include a metal material. The metal material may include a metal material such as copper (Cu), aluminum (Al), silver (Ag), tin (Sn), gold (Au), nickel (Ni), lead (Pb), titanium (Ti), or alloys thereof. The second via layer 230 may each include an electroless plating layer (or chemical copper) as a seed layer and an electrolytic plating layer (or electrolytic copper) as a plating layer, but an embodiment thereof is not limited thereto. A sputtering layer may be formed instead of chemical copper as the electroless plating layer. The second via layer 230 may perform various functions according to the design of the corresponding layer. For example, a ground via, a power via, a signal via, and the like may be included. Here, the signal vias may include vias for transferring various signals, for example, a data signal, other than a ground via and a power via.

The second wiring layers 220 and the second via layer 230 may be integrated with each other, respectively, but an embodiment thereof is not limited thereto. The second wiring layer 220 and/or the second via layer 230 may be formed by one of a semi-additive process (SAP), a modified semi-additive process (MSAP), tenting (TT) or a subtractive method, but an embodiment thereof is not limited thereto, and any method for configuring a circuit on a printed circuit board may be used without limitation.

The second substrate 201 may include a first post 221 for mounting a first semiconductor chip 270 to be described later. The first post 221 may protrude to the outermost side of the second substrate 201 and may perform a function of a post to facilitate connection with the first semiconductor chip 270. The first post 221 may include a metal material. As a metal material, copper (Cu), aluminum (Al), silver (Ag), tin (Sn), gold (Au), nickel (Ni), lead (Pb), titanium (Ti) or an alloy thereof may be used. The first post 221 may be formed in the same manner as the second wiring layer 220, but an embodiment thereof is not limited thereto, and any method for forming a generally used metal post may be used without limitation. For example, the first post 221 may be formed first and the other components of the second substrate 201 may be formed, or a method such as combining the first post 221 with a separately manufactured metal pillar may be used.

The second substrate 201 may further include a first surface treatment layer 222 disposed on the first post 221. The first surface treatment layer 222 may increase coupling between the first semiconductor chip 270 and the first post 221 when the first semiconductor chip 270 to be described later is mounted. The first surface treatment layer 222 may be formed by organic solderability preservative (OSP), hot air solder level (HASL), electroless nickel/immersion gold (ENIG), and electroless nickel/electroless palladium/immersion gold (ENEPIG) methods, and also, as the first surface treatment layer 222, an electroless plating layer may be formed.

The second substrate 201 may include a cavity penetrating through at least a portion of the second insulating layer 210. The cavity may be used as a space for mounting the first SERDES chip to be described later. Any general method of processing a cavity in a printed circuit board may be used as a method of forming the cavity without limitation.

The first semiconductor chip 270 may be disposed on the second substrate 201, and the first semiconductor chip 270 may be configured as an integrated circuit (IC) in which hundreds to millions of elements or more are integrated into a chip. The first semiconductor chip 270 may be a processor chip such as a central processor (CPU), a graphics processors (GPU), a field programmable gate array (FPGA), a digital signal processor, an encryption processor, a microprocessor, a microcontroller, specifically an application processor (AP), but an embodiment thereof is not limited thereto, and may be configured as a logic chip such as an analog-to-digital converter, an specific IC (ASIC) memory controller (MC) chip, or may be a memory chip such as a Dynamic random access memory (DRAM), a static random access memory (SRAM), a flash memory chip, a phase-change random access memory (PRAM) chip, a magnetic random access memory (MRAM) chip, a resistive random access memory (RRAM) chip, an electrically erasable and programmable read-only memory (EEPROM) chip, or a high bandwidth memory (HBM), and the chips may be disposed in combination with each other.

In the first semiconductor chip 120, a surface on which a pad for connecting to the second substrate 201 is disposed may become an active surface, and an opposite surface may become an inactive surface. The first semiconductor chip 270 may be formed based on an active wafer, and in this case, silicon (Si), germanium (Ge), gallium arsenide (GaAs), or the like may be used as a base material forming the body. Various circuits may be formed in the body of the first semiconductor chip 270.

The first semiconductor chip 270 may be connected to the second substrate 201 through the first connection member 271. The first connection member 271 may allow the first semiconductor chip 270 to be mounted on the second substrate 201 and may physically and/or electrically connect the first semiconductor chip 270 to the second substrate 201. The first semiconductor chip 270 may be formed of a conductive material, for example, solder, but the material of the first connection member 271 is not limited thereto. Also, the first connection member 271 may be configured a land, a ball, a pin, and the like, but an embodiment thereof is not limited thereto. The first connection member 271 may be formed as a multilayer or a single layer. When the first connection member 271 is formed in multiple layers, the first connection member 271 may include a copper pillar and solder, and when formed in a single layer, the first connection member 271 may include tin-silver solder or copper, but an embodiment thereof is not limited thereto. The number, the spacing, the arrangement, or the like, of the first connection members 271 are not limited to any particular example, and may be sufficiently modified according to design matters for those skilled in the art. For example, the number of first connection members 271 may be tens to thousands, or may be more or less than the above-mentioned number.

The first package 200 of the semiconductor package according to the embodiment may include a first SERDES chip 250 embedded in the second substrate 201. In embodiments, a SERDES chip may refer to a combination of a serializer and a deserializer, and may be represented as a may be represented as a serializer/parallelizer, serializer/deserializer, or may be represented as a serializer/parallelizer, but an embodiment thereof is not limited thereto, and the SERDES chip may refer to a semiconductor chip which may include a circuit for performing serializer and deserializer functions. However, an embodiment thereof is not limited thereto, and may include the example in which a circuit performing the SERDES function may be directly implemented on the second substrate 201 and a SERDES function may be performed in the region of the second substrate 201. That is, the SERDES chip may be represented as a chip for performing the function, but an embodiment thereof is not limited thereto, and the region in which the SERDES circuit is implemented in the second substrate 201 and is integrated with the second substrate 201 may correspond to the SERDES chip.

The first SERDES chip 250 may receive a command from an external entity and may transmit the command to an external entity in the form of data, or may receive data from an external entity and convert the data into a command, which may is to visually divide commands and data, to multiplex the commands and data, to serialize the commands and data, and to transmit the commands and data in a simplified state, and the command and data may be analyzed through time-division demultiplexing. As described above, the first SERDES chip 250 may function as an interconnection connecting an external entity to an external entity. Specifically, the first SERDES chip may correspond to an interface for performing die-to-die interconnection between semiconductor chips, and more specifically, the first SERDES chip may operate as an interface between a memory controller and a memory. For example, the first SERDES chip 250 may serially convert parallel data received from the first semiconductor chip 270 into serial data and may transmit the serial data to the second semiconductor chip 370. Alternatively, the first SERDES chip 250 may convert serial data received from the second semiconductor chip 370 into parallel data and may transmit the parallel data to the first semiconductor chip 270.

In the semiconductor package according to the embodiment, the first SERDES chip 250 may include a serializer chip. In this case, the first SERDES chip 250 may function as a serializer for converting parallel data received from the first semiconductor chip 270 into serial data. However, an embodiment thereof is not limited thereto, and the first SERDES chip 250 may include a deserializer chip. In this case, the first SERDES chip 250 may perform a function of converting serial data received from the second semiconductor chip 370 into parallel data. However, an embodiment thereof is not limited thereto, and by adopting half duplex, the first SERDES chip 250 may include a transmitter and a receiver such that a chip may perform transmission and reception functions.

In the semiconductor package according to the embodiment, the first SERDES chip 250 included in the first package 200 may include a serializer chip. The first SERDES chip 250 may include a first connection pad 251, and the first connection pad 251 may include an input connection pad for receiving data from the first semiconductor chip 270 and an output connection pad for transmitting converted data to an external entity. Also, the first connection pad 251 may further include various connection pads connected to an external entity, such as a power connection pad.

In the first connection pad 251 of the first SERDES chip 250, the number of input connection pads may be greater than the number of output connection pads. Since the serializer chip performs a function of converting a signal input in parallel into a serial signal and transmitting the signal to the second package 300, the signal input in parallel may be time-integrated and transmitted to the second package 300 in a unified state. Accordingly, the number of input connection pads for receiving data from the first semiconductor chip 270 may be greater than the number of output pads for transmitting converted data to an external entity.

That is, connection between the plurality of first semiconductor chips 270 may be simplified through a serializer. For example, when an N number of parallel signals received from the first semiconductor chip 270 may be transmitted by being converted into a serial signal, the first package 200 may reduce the number of connections at a ratio of N:1 as compared to the first semiconductor chip 270. That is, by implementing the first package 200 in such a manner that the first SERDES chip 250 is embedded in the second substrate 201, it may not be necessary to implement a redistribution layer (RDL) for direct connection with the first semiconductor chip 270. That is, the number of connections may be reduced by changing the design of the first SERDES chip 250 and the second substrate 201 connecting the chips and the design of the first substrate 100 without implementing a redistribution layer, which may be significant in that the redistribution layer including microcircuits may be simplified and even the redistribution layer may not be provided. Since the circuit having a fine pitch is reduced, the configuration may greatly contribute to improving yield of the second substrate 201 and first substrate 100, and may further improve reliability.

The first package 200 of the semiconductor package according to the embodiment may include a first adhesive member 260. The first SERDES chip 250 may be disposed in a cavity of the second substrate 201, and the first SERDES chip 250 may be attached to a bottom surface of the cavity through the first adhesive member 260. As the first adhesive member 260, an adhesive film such as a general die attach film (DAF) may be used, but an embodiment thereof is not limited thereto, and any means to attach other components such as an electronic component or a semiconductor chip to the printed circuit board, such as a generally used tape, may be used without limitation. In the first SERDES chip 250, the first connection pad 251 may be disposed only on an upper surface, and in this case, the upper surface on which the first connection pad 251 is disposed may be an active surface. A lower surface on which the first connection pad 251 is not disposed may become an inactive surface, and the first adhesive member 260 may be bonded to the inactive surface of the first SERDES chip 250 such that the first SERDES chip 250 may be attached to the second substrate 201.

The second substrate 201 may further include a second solder resist layer 240 on an outermost side. The second solder resist layer 240 may protect the second substrate 201 from an external entity and may be disposed on an uppermost side of the second substrate 201 and/or a lowermost side of the second substrate 201. The second solder resist layer 240 may include a thermosetting resin and an inorganic filler dispersed in the thermosetting resin, and may not include glass fiber. The insulating resin may be a photosensitive insulating resin, and the filler may be an inorganic filler and/or an organic filler, but an embodiment thereof is not limited thereto. However, the material of the second solder resist layer 240 is not limited thereto, and if desired, any material of solder resist used in the field of a printed circuit board, such as polymer materials, may be used without limitation. The second solder resist layer 240 may include an opening, and a portion of the second wiring layer 220 may be exposed to an external entity through the opening and may perform a function of a pad connected to other components, or a first post 221 protruding from the second solder resist layer 240 may be disposed.

The number of layers of the second insulating layer 210, the second wiring layer 220 and the second via layer 230 and the depth of the cavity may be varied depending on a design. Also, as illustrated in FIG. 3, the second substrate 201 may have a pattern structure in which the second wiring layer 220 of the lowermost side is embedded by the second insulating layer 210 of a lowermost side, and may have a coreless structure not including a core insulating layer. However, an embodiment thereof is not limited thereto, and the second substrate 201 may have a coreless structure in which the second wiring layer 220 on the uppermost side is embedded by the second insulating layer 210 on an uppermost side. However, an embodiment thereof is not limited thereto, and the second substrate 201 may have a structure of a core substrate.

The first package 200 may further include a molding material disposed to surround the second substrate 201 and the second semiconductor chip 370 and protecting the first package 200. In this case, the molding material may be an epoxy molding compound (EMC), but an embodiment thereof is not limited thereto, and any component used as a molding material in the field of semiconductor package technology may be used without limitation. As such, without being limited to the configuration illustrated in FIG. 3, as the first package 200, any component available to those skilled in the art in the field of a printed circuit board and a semiconductor package may be used without limitation, and other components may be further included.

The second package 300 may include a third substrate 301, a second semiconductor chip 370 disposed on the third substrate 301, a second connection member 371 connecting the second semiconductor chip 370 to each other, and a second SERDES chip embedded in the third substrate 301.

The second package 300 may be configured as a chip package including the second semiconductor chip 370, and may have a structure in which the second semiconductor chip 370 is mounted on the third substrate 301. The third substrate 301 may be configured as a printed circuit board and may have a fine structure to be connected to the second semiconductor chip 370. The third substrate 301 may include a third insulating layer 310, a third wiring layer 320 disposed on or in the third insulating layer 310, and a third via layer 330 penetrating through at least a portion of the third insulating layer 310 to connect the third wiring layers 320 to each other.

The third insulating layer 310 may include a plurality of insulating layers, and each third insulating layer 310 may include an insulating material. The insulating material may include a thermosetting resin such as epoxy resin, a thermoplastic resin such as polyimide, or a material including an inorganic filler, an organic filler, and/or glass fiber (glass fiber, glass cloth, and/or glass fabric) together with the resins. The insulating material may be a photosensitive material and/or a non-photosensitive material. For example, the insulating material of the first insulating layer 110 may be prepreg (PPG) or resin coated copper (RCC) insulating material, but an embodiment thereof is not limited thereto, and the insulating material may be Ajinomoto build-up film (ABF), photoimageable dielectric (PID), FR-4, bismaleimide triazine (BT), and the like. However, an embodiment thereof is not limited thereto, and if desired, other polymer materials having excellent rigidity may be used. The third insulating layer 310 may include a plurality of third insulating layers 310, and the plurality of third insulating layers 310 may not include the same material, and may include different insulating materials for each layer. For example, in a region connected to the second semiconductor chip 370, as the third insulating layer 310, a photoimageable dielectric (PID) may be used to form a microcircuit, but an embodiment thereof is not limited thereto.

The third wiring layer 320 may include a plurality of wiring layers, and each third wiring layer 320 may include a metal material. As a metal material, copper (Cu), aluminum (Al), silver (Ag), tin (Sn), gold (Au), nickel (Ni), lead (Pb), titanium (Ti), or alloys thereof may be used. Each of the third wiring layer 320 may include an electroless plating layer (or chemical copper) as a seed layer and an electrolytic plating layer (or electrolytic copper) as a plating layer, but an embodiment thereof is not limited thereto. A sputtering layer may be formed instead of chemical copper as the electroless plating layer. If desired, copper foil may be further included. The third wiring layer 320 may perform various functions according to a design of the respective layer. For example, a ground pattern, a power pattern, a signal pattern, and the like, may be included. Here, the signal pattern may include various signals other than a ground pattern and a power pattern, for example, a data signal. Each of these patterns may include a line pattern, a plane pattern, and/or a pad pattern. Among the third wiring layer 320, the third wiring layer 320 disposed on an uppermost side may have a structure exposed from the third insulating layer 310, and a surface treatment layer may be further included on the exposed surface.

The third via layer 330 may include a plurality of via layers, and each third via layer 330 may include a micro-via. A micro-via may be a filled via for filling a via hole or a conformal via disposed along a wall surface of a via hole. The micro-vias may be arranged in a stacked type and/or a staggered type. Each third via layer 330 may include a metal material. The metal material may include copper (Cu), aluminum (Al), silver (Ag), tin (Sn), gold (Au), nickel (Ni), lead (Pb), titanium (Ti), or alloys thereof. Each of the third via layer 330 may include an electroless plating layer (or chemical copper) as a seed layer and an electrolytic plating layer (or electrolytic copper) as a plating layer, but an embodiment thereof is not limited thereto. A sputtering layer may be formed instead of chemical copper as the electroless plating layer. The third via layer 330 may perform various functions according to a design of the corresponding layer. For example, a ground via, a power via, a signal via, and the like may be included. Here, the signal vias may include vias for transferring various signals, for example, a data signal, other than a ground via and a power via.

The third wiring layers 320 and the third via layers 330 may be integrated with each other, respectively, but an embodiment thereof is not limited thereto. The third wiring layer 320 and/or the third via layer 330 may be formed by one of a semi-additive process (SAP), a modified semi-additive process (MSAP), tenting (TT) or a subtractive method, but an embodiment thereof is not limited thereto, and any construction method for configuring a circuit on a printed circuit board may be used without limitation.

The third substrate 301 may include a second post 321 for mounting a second semiconductor chip 370 to be described later. The second post 321 may protrude to the outermost side of the third substrate 301 and may perform a function of a post to be easily connected to the second semiconductor chip 370. The second post 321 may include a metal material, such as copper (Cu), aluminum (Al), silver (Ag), tin (Sn), gold (Au), nickel (Ni), lead (Pb), titanium (Ti) or an alloy thereof. The second post 321 may be formed in the same manner as the third wiring layer 320, but an embodiment thereof is not limited thereto, any method for forming a generally used metal post may be used without limitation. For example, the second post 321 may be formed first and the other components of the third substrate 301 may be formed, or a method of combining the second post 321 with a separately manufactured metal pillar may be used.

The third substrate 301 may further include a second surface treatment layer 322 disposed on the second post 321. The second surface treatment layer 322 may increase coupling between the second semiconductor chip 370 and the second post 321 when the second semiconductor chip 370 to be described later is mounted. The second surface treatment layer 322 may be formed by an organic solderability preservative (OSP) method, a hot air solder level (HASL) method, an electroless nickel/immersion gold (ENIG) method, an electroless nickel/electroless palladium/immersion gold (ENEPIG) method, and as the second surface treatment layer 322, an electroless plating layer may be formed.

The third substrate 301 may include a cavity penetrating through at least a portion of the third insulating layer 310. The cavity may be used as a space for mounting the second SERDES chip to be described later. As a method of forming the cavity, any general method of processing a cavity in a printed circuit board in general may be used without limitation.

The second semiconductor chip 370 may be disposed on the third substrate 301, and the second semiconductor chip 370 may be an integrated circuit (IC) in which hundreds to millions of elements or more are integrated into a chip. The second semiconductor chip 370 may be a processor chip such as a central processor (CPU), a graphics processors (GPU), a field programmable gate array (FPGA), a digital signal processor, an encryption processor, a microprocessor, a microcontroller, specifically an application processor (AP), but an embodiment thereof is not limited thereto, and may be configured as a logic chip such as an analog-to-digital converter, an specific IC (ASIC) memory controller (MC) chip, or may be a memory chip such as a Dynamic random access memory (DRAM), a static random access memory (SRAM), a flash memory chip, a phase-change random access memory (PRAM) chip, a magnetic random access memory (MRAM) chip, a resistive random access memory (RRAM) chip, an electrically erasable and programmable read-only memory (EEPROM) chip, or a high bandwidth memory (HBM), and the chips may be disposed in combination with each other.

In the second semiconductor chip 370, a surface on which a pad for connecting to the third substrate 301 is disposed may become an active surface, and an opposite surface may become an inactive surface. The second semiconductor chip 370 may be formed based on an active wafer, and in this case, silicon (Si), germanium (Ge), gallium arsenide (GaAs), or the like may be used as a base material forming the body. Various circuits may be formed in the body of the second semiconductor chip 370.

The second semiconductor chip 370 may be connected to the third substrate 301 through the second connection member 371. The second connection member 371 may allow the second semiconductor chip 370 to be mounted on the third substrate 301 and may physically and/or electrically connect the second semiconductor chip 370 to the third substrate 301. The second connection member 371 may be formed of a conductive material, for example, solder, but the material of the second connection member 371 is not limited thereto. Also, the second connection member 371 may include a land, a ball, a pin, and the like, but an embodiment thereof is not limited thereto. The second connection member 371 may be formed as multiple layers or a single layer. When formed in multiple layers, the second connection member 371 may include a copper pillar and solder, and when formed in a single layer, the second connection member 371 may include tin-silver solder or copper, but an embodiment thereof is not limited thereto. The number, a spacing, and arrangement of the second connection members 371 are not limited to any particular example, and may be sufficiently modified according to design matters for those skilled in the art. For example, the number of second connection members 371 may be tens to thousands, and may be more or less the above-mentioned number.

The second package 300 of the semiconductor package according to the embodiment may include a second SERDES chip 350 embedded in the third substrate 301. The description of the second SERDES chip may be as above.

The second SERDES chip 350 may receive data from an external entity, and may transmit the data by converting the data into a command, or conversely, the second SERDES chip 350 receive a command from an external entity and may convert the command into a data format, which may be to visually divide a command and data, to multiplex the command and data, may serialize the command and data, and may transmit the command and data in a simplified state, and may analyze the command and data again through time-division demultiplexing.

As described above, the second SERDES chip 350 may function as an interconnection for connecting an external entity to an external entity. Specifically, the second SERDES chip 350 may correspond to an interface for performing die-to-die interconnection between semiconductor chips together with the first SERDES chip 250, and more specifically, the second SERDES chip 350 may operate as an interface between a memory controller and a memory. For example, the second SERDES chip 350 may convert serial data received from the first package 200 into parallel data and may transmit the converted data to the second semiconductor chip 370. Alternatively, the second SERDES chip 350 may convert serial data received from the second semiconductor chip 370 into parallel and may transmit the parallel data to the first semiconductor chip 270 of the first package 200.

In the semiconductor package according to the embodiment, the second SERDES chip 350 may include a deserializer chip. In this case, a function of converting the command received from the first semiconductor chip 270 by the first SERDES chip 250 and converting a serial signal transmitted through the first package 200 and the first substrate 100 into parallel data by the second SERDES chip 350 may be performed, and the converted parallel data may be transmitted to the second semiconductor chip 370. That is, the second SERDES chip 350 may perform a function of a deserializer or parallelizer. However, an embodiment thereof is not limited thereto, and the second SERDES chip 350 may include a serializer chip, and in this case, the second SERDES chip 350 may function as a serializer for converting parallel data received from the second semiconductor chip 370 into serial data by the second SERDES chip 350. However, an embodiment thereof is not limited thereto, and by adopting half duplex, the second SERDES chip 350 may have a transmitter and a receiver such that one chip may perform transmission and reception functions.

In the semiconductor package according to the embodiment, the second SERDES chip 350 included in the second package 300 may include a deserializer chip. The first SERDES chip 250 may include a second connection pad 351, and the second connection pad 351 may include an input connection pad for receiving data from the first semiconductor chip 270 of the first package 200, and an output connection pad for transmitting the converted data to the second semiconductor chip 370. Also, the second connection pad 351 may further include various connection pads connected to an external entity, such as a power connection pad.

In the second connection pad 351 of the second SERDES chip 350, the number of output connection pads may be greater than the number of input connection pads. The deserializer chip may convert a serially input signal into a parallel signal and may transmit the signal to the second package 300, and accordingly, the serial signal passing through the first SERDES chip 250 may be analyzed as a command and data through time-division demultiplexing again. The parallel signal analyzed as above may be transmitted to the second semiconductor chip 370 in a multiplexed state. Accordingly, the number of input connection pads for receiving the serial signal converted by the first SERDES chip 250 may be less than the number of output pads for transmitting the converted parallel data to the second semiconductor chip 370, which may indicate that the number of output connection pads of the second connection pad 351 may be greater than the number of input connection pads.

That is, the signals simplified through the serializer may be inversely converted into original commands and data through the deserializer. That is, the simplified signal may be converted again and transmitted to another semiconductor chip. For example, in the case in which one serial signal transmitted from the first package may be converted into an N number of parallel signals, the second package 300 may reduce the number of connections at a ratio of 1:N as compared to the second semiconductor chip 370. That is, even when a single connection between the second package 300 and the first substrate 100 is included, the second substrate 201 and the second semiconductor chip 370 may implement a number of N connections, which may be to analyze the signal converted by the serializer, and accordingly, the redistribution layer including microcircuits may be simplified and even the redistribution layer may not be provided, which may be significant. Since the circuit with fine pitch is reduced, the configuration may greatly contribute to improving yield of the third substrate 301 and the first substrate 100, and may further improve reliability. As an example, conversion may be performed at a ratio of 1:N, but an embodiment thereof is not limited thereto, and serial-to-parallel conversion may be performed at a ratio of 1:M, which is different from that of the first SERDES chip 250.

The second package 300 of the semiconductor package according to the embodiment may include a second adhesive member 360. The second SERDES chip 350 may be disposed in the cavity of the third substrate 301, and the second SERDES chip 350 may be attached to a bottom surface of the cavity through the second adhesive member 360. As the second adhesive member 360, an adhesive film such as a general die attach film (DAF) may be used, but an embodiment thereof is not limited thereto, and a generally used tape may be used, and any means for attaching other components such as an electronic component or a semiconductor chip to the printed circuit board, such as a generally used tape, may be used without limitation. In the second SERDES chip 350, the second connection pad 351 may be disposed only on an upper surface, and in this case, the upper surface on which the second connection pad 351 is disposed may be an active surface. The lower surface on which the second connection pad 351 is not disposed may become an inactive surface, and the second adhesive member 360 may be bonded to the inactive surface of the second SERDES chip 350 such that the second SERDES chip 350 may be attached to the third substrate 301.

The third substrate 301 may further include a third solder resist layer 340 on an outermost side. The third solder resist layer 340 may protect the third substrate 301 from an external entity and may be disposed on an uppermost side of the third substrate 301 and/or a lowermost side of the third substrate 301. The third solder resist layer 340 may include a thermosetting resin and an inorganic filler dispersed in the thermosetting resin, and may not include glass fiber. The insulating resin may be a photosensitive insulating resin, and the filler may be an inorganic filler and/or an organic filler, but an embodiment thereof is not limited thereto. However, the material of the third solder resist layer 340 is not limited thereto, and if desired, any solder resist material used in the field of printed circuit board, such as other polymer materials, may be used without limitation. The third solder resist layer 340 may include an opening, and a portion of the third wiring layer 320 may be exposed to an external entity through the opening and may perform a function of a pad connected to other components, or a second post 321 protruding from the third solder resist layer 340 may be disposed.

The number of layers of the third insulating layer 310, the third wiring layer 320 and the third via layer 330 and the depth of the cavity may be varied depending on a design. Also, as illustrated in FIG. 3, the third substrate 301 may have a structure of a pattern in which the third wiring layer 320 of the lowermost side may be embedded by the third insulating layer 310 of the lowermost side, and may have a coreless structure not including a core insulating layer. may However, an embodiment thereof is not limited thereto, and the third substrate 301 may have a coreless structure in which the third wiring layer 320 on the uppermost side is embedded by the third insulating layer 310 on the uppermost side. However, an embodiment thereof is not limited thereto, and the third substrate 301 may have a structure of a core substrate.

The second package 300 may further include a molding material disposed to surround the third substrate 301 and the second semiconductor chip 370 and protecting the second package 300. In this case, the molding material may be an epoxy molding compound (EMC), but an embodiment thereof is not limited thereto, and any component used as a molding material in the field of semiconductor package may be used without limitation. As such, the second package 300 may not be limited to the configuration illustrated in FIG. 3, and a component which may be used by those skilled in technical field of a printed circuit board and a semiconductor package may be used without limitation, and other components may be further included.

The second package 300 may be symmetrical with the first package 200, but this is merely for ease of description, and the second package 300 may have a different configuration from that of the first package 200.

A semiconductor package according to the embodiment may include a 1-1 connection member 401 connecting the first substrate 100 to the first package 200, and a 2-1 connection member 402 connecting the first substrate 100 to the second package 300. Each of the 1-1 connection member 401 and 2-1 connection member 402 may be formed of a conductive material, for example, solder, but the material of the 1-1 connection member 401 and the 2-1 connection member 402 is not limited to any particular example. Also, the 1-1 connection member 401 and/or the 2-1 connection member 402 may be configured as a land, a ball, a pin, or the like, but an embodiment thereof is not limited thereto. The 1-1 connection member 401 and the 2-1 connection member 402 may be formed in multiple layers or a single layer. When formed in multiple layers, the 1-1 connection member 401 and the 2-1 connection member 402 may include a copper pillar and solder, and when formed in a single layer, the 1-1 connection member 401 and the 2-1 connection member 402 may include tin-silver solder or copper, but an embodiment thereof is not limited thereto. The number, a spacing, and arrangement of the 1-1 connection members 401 and the 2-1 connection members 402 are not limited to any particular example, and may be sufficiently modified according to design matters for those skilled in the art.

In the first package 200, the number of first connection members 271 connecting the first semiconductor chip 270 to the second substrate 201 may be greater than the number of 1-1 connection members connecting the first substrate 100 to the first package 200. Since the parallel signal generated by the first semiconductor chip 270 is converted into a serial signal by the first SERDES chip 250 and is transmitted to the first substrate 100, it may be sufficient to provide the number of signal paths smaller than the number of signal paths generated by the first semiconductor chip 270 from the first package 200 to the first substrate 100, such that the first substrate 100 and the first package 200 may be connected to each other with fewer connections.

Also, in the second package 300, the number of second connection members 371 connecting the second semiconductor chip 370 to the third substrate 301 may be greater than the number of 2-1 connection members 402 connecting the first substrate 100 to the second package 300, which may be indicated in the opposite manner to the aforementioned embodiment. That is, since the signal is transmitted to the second package 300 in a state in which the number of paths for signals transmitted from the first package 200 to the first substrate 100 is relatively small, the number of connections between the first substrate 100 and the second package 300 may be maintained to be small, but since the serial signal is converted back to a parallel signal through the second SERDES chip 350 and is transmitted to the second semiconductor chip 370, the second substrate 201 and the second semiconductor chip 370 may require more signal paths than the number of signal paths of the first substrate 100 and the second package 300. Accordingly, even when the first substrate 100 and the second package 300 are connected with fewer connections, the required connection between the second substrate 201 and the second semiconductor chip 370 may be sufficiently performed.

Also, the pitch of the first connection member 271 may be formed smaller than the pitch of the 1-1 connection member 401, which may indicate that the pitch of the second wiring layer 220 connected to the first connection member 271 in the second substrate 201 may be smaller than the pitch of the second wiring layer 220 connected to the 1-1 connection member 401. In embodiments, the pitch (pitch) may be measured by imaging a cross-section of the printed circuit board using a scanning microscope, and an average pitch may be the average value of pitches between wirings measured at five random points adjacent to each other. That is, the wiring included in the second wiring layer 220 disposed on the uppermost side connected to the first connection member 271 may be may be a high-density circuit having a smaller line/space (L/S) than a wiring included in the second wiring layer 220 disposed on the lowermost side connected to the 1-1 connection member 401. As described above, since the number of first connection members 271 is greater than the number of 1-1 connection members 401, the pitch of the first connection member 271 may be smaller than the pitch of the 1-1 connection member 401, which may be similar to the configuration in which the pitch of the second connection member 371 may be formed smaller than the pitch of the 2-1 connection member 402, and which may indicate that the pitch of the third wiring layer 320 connected to the second connection member 371 in the third substrate 301 may be smaller than the pitch of the third wiring layer 320 connected to the 2-1 connection member 402.

In the case of a fan-in package or a fan-out package generally used to mount a semiconductor chip on a printed circuit board, the semiconductor chip may be connected through a redistribution layer. However, a general redistribution layer may be a fine wiring layer, and it may not be easy to implement the layer, and defects may often occur in the process of implementing the fine redistribution layer. Also, as the size of the semiconductor chip increases, the size of the redistribution layer used in the fan-in package or fan-out package may also increase. As the size of the substrate increases, defects in the redistribution layer including fine wiring may occur more frequently. However, the semiconductor package according to the embodiment may easily perform signal transmission with the first semiconductor chip 270 and the second semiconductor chip 370 without the first package 200 and the second package 300 implementing a redistribution layer. Also, since the implementation of redistribution layer, which is fine wiring, may be designed to be reduced or almost absent, reliability may be greatly improved, and since each semiconductor chip is mounted on the first substrate 100 after being packaged, yield may be improved. Also, since the packaged first package 200 and second package 300 are mounted on the first substrate 100, respectively, each package may be mounted on the first substrate 100 through the 1-1 connection member 401 and the 2-1 connection member 402 in a state in which the pitch is sufficiently extended.

In the semiconductor package according to the embodiment, the first semiconductor chip 270 and the second semiconductor chip 370 may be electrically connected to each other. Specifically, the first semiconductor chip 270 and the second semiconductor chip 370 may be electrically connected to each other by a path passing through the first SERDES chip 250, the second substrate 201, the first substrate, the third substrate 301, and the second SERDES chip 350. As illustrated in FIG. 3, a plurality of parallel signals from the first semiconductor chip 270 may be converted into a unified serial signal by the first SERDES chip 250, and a serial signal from the first SERDES chip 250 may be transmitted from the second substrate 201 of the first package 200 to the first substrate 100. A high-speed serial signal transferred through the first wiring layer 120 of the first substrate 100 may move to the third substrate 301 of the second package 300 and may be input to the second SERDES chip 350. The second SERDES chip 350 may convert the serial signal back into a parallel signal, and the parallelized signal may be connected to the second semiconductor chip 370. The signal transmission path may be confirmed by analyzing the finished semiconductor package layer by layer. That is, while removing the first semiconductor chip 270 and the second semiconductor chip 370, the surface may be removed one by one with respect to the second wiring layer 220 and the third wiring layer 320 connected to the first SERDES chip 250 and second SERDES chip 250, such that it may be confirmed that the signal path is formed by repeating the process of checking whether the subsequent second wiring layer 220 and the third wiring layer 320 are connected to the aforementioned wiring layer. However, an embodiment thereof is not limited thereto, in the case in which there are other methods to analyze the signal path, the method may be used without limitation.

In this case, each path may be connected through the shortest distance. Also, signal transmission in the first substrate 100 may be connected through the shortest path, but an embodiment thereof is not limited thereto. Since signal transmission through the first wiring layer 120 in the first substrate 100 corresponds to transmission of a high-speed signal converted into a serial signal through the first SERDES chip 250, signal transmission in the first substrate 100 may have reduced signal loss. Accordingly, as described above, the 1-1 insulating layer 111 may include an insulating material having a lower dissipation factor (Df) to minimize signal loss compared to other first insulating layers 110. Also, to minimize the loss of the high-speed signal, each of the second via layer 230 and the third via layer 330 used as a high-speed signal transmission path of the second substrate 201 and the third substrate 301 may have a stacked via form. Also, in selecting materials for each component, a method for reducing signal loss may be considered, such that any configuration used in the technical field related to a printed circuit board and a semiconductor package may be used without limitation.

In FIG. 3, the signal path may be merely represented as an example, and two parallel signals or a plurality of parallel signals may not have to be converted into a serial signal. However, an embodiment thereof is not limited thereto, and more signal paths may be present, and various signal paths such as a power line and a ground line may be present as a signal path connected to a semiconductor chip.

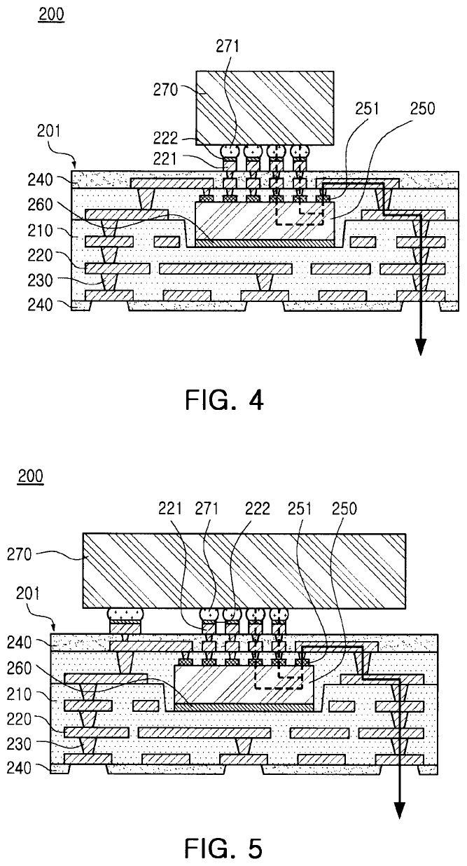

FIG. 4 is a cross-sectional diagram illustrating a first package of a semiconductor package according to an embodiment. Since FIG. 4 illustrates only the first package 200 in the semiconductor package according to the embodiment in FIG. 3, overlapping descriptions will not be provided.

In the first package 200, the width of the first semiconductor chip 270 may be narrower than the width of the second substrate 201, which may correspond to a fan-out package. Differently from the general fan-out package as described above, the first package 200 may be implemented to correspond to the fan-out package without including a redistribution layer. For example, the pitch may be adjusted such that the number of 1-1 connection members 401 may be less than the number of first connection members 271, while wiring density of the second wiring layer may be substantially the same instead of being different for each layer.

In embodiments, the configuration of being substantially the same may refer to being similar, and may include, for example, an error in a manufacturing process or an error in a measurement process.

Although FIG. 4 illustrates only the first package 200 as an embodiment, an embodiment thereof is not limited thereto, and the same description may be applied to the second package 300.

FIG. 5 is a cross-sectional diagram illustrating a first package according to another embodiment. Among the components in FIG. 5, overlapping descriptions will not be provided for the first package 200.

In the first package 200, the width of the first semiconductor chip 270 may be similar to or substantially the same as the width of the second substrate 201, which may correspond to a fan-in package. Differently from the general fan-in package as described above, the first package 200 may be implemented to correspond to the fan-in package without including a fine wiring in the second substrate 201 to correspond to the width of the first semiconductor chip 270. For example, the pitch may be adjusted such that the number of 1-1 connection members 401 may be less than the number of first connection members 271, while wiring density of the second wiring layer may be substantially the same instead of being different for each layer.

Although FIG. 5 illustrates only the first package 200 as an embodiment, the same description may be applied to the second package 300, but an embodiment thereof is not limited thereto.

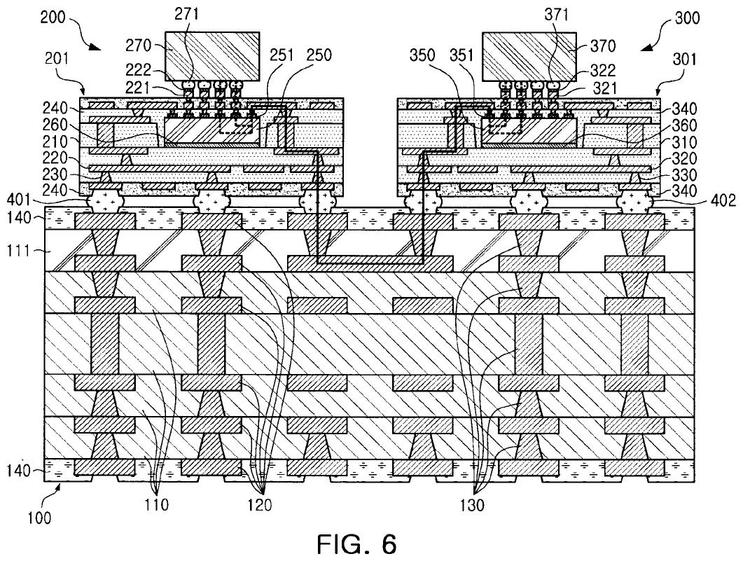

FIG. 6 is a cross-sectional diagram illustrating a semiconductor package according to another embodiment.

Referring to FIG. 6, a first package 200 of a semiconductor package according to another embodiment may be configured as a cored-type substrate. The second insulating layer 210 may include a core layer, and may be an insulating material such as prepreg (PPG) or resin coated copper (RCC), or copper clad laminate (CCL), but an embodiment thereof is not limited thereto. The first SERDES chip 250 may be mounted in a cavity formed in the core layer of the second insulating layer 210, but an embodiment thereof is not limited thereto. FIG. 6 illustrates that the second substrate 201 of the first package 200 and the third substrate 301 of the second package 300 may be cored-type substrates, but an embodiment thereof is not limited thereto, and the first package 200 and the second package 300 may not be necessarily limited to substrates of the same type.

Among the components other than the second insulating layer 210 of the first package 200, the same components as those of the semiconductor package according to another embodiment may be applied to the semiconductor package according to another embodiment, and thus, overlapping descriptions will not be provided.

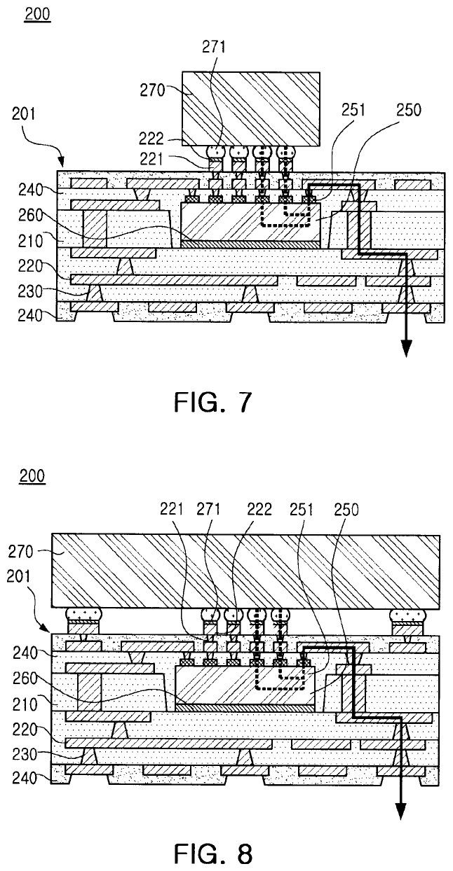

FIG. 7 is a cross-sectional diagram illustrating a first package of a semiconductor package according to another embodiment. FIG. 8 is a cross-sectional diagram illustrating a first package according to another embodiment.

Since FIG. 7 illustrates only the first package 200 in a semiconductor package according to another embodiment in FIG. 6, overlapping descriptions will not be provided. Referring to FIG. 7, a first package of a semiconductor package according to another embodiment may correspond to a fan-out package.

Referring to FIG. 8, a first package according to another embodiment may correspond to a fan-in package.

Although FIGS. 7 and 8 illustrate only the first package 200 as an embodiment, but an embodiment thereof is not limited thereto, the same description may be applied to the second package 300.

According to the aforementioned example embodiments, a semiconductor package which may perform die-to-die interconnection in a package including a semiconductor chip may be provided.

Also, in die-to-die interconnection, a semiconductor package including a simplified wiring structure may be provided.

Also, a semiconductor package for improving reliability may be provided.

In the present disclosure, a shape on a cross-section may refer to a cross-sectional shape when the object is vertically cut, or a cross-sectional shape when the object is viewed from a side-view. Also, a shape on a plane may be a shape when the object is horizontally cut, or a planar shape when the object is viewed from a top-view or a bottom-view.

In the present disclosure, the lower side, the lower side, the lower surface, or the like, are used to refer to the direction the toward mounting surface of the semiconductor package including the organic interposer based on the cross-section of the drawing, and the upper side, the upper side, the upper surface, or the like, are the opposite direction was used. However, the direction is defined for ease of description, and the scope of the claims is not limited to any particular example by the description of this direction.

In the example embodiments, the term “connected” may not only refer to “directly connected” but also include “indirectly connected” by may refer to of an adhesive layer, or the like. Also, the term “electrically connected” may include both of the case in which elements are “physically connected” and the case in which elements are “not physically connected.” Further, the terms “first,” “second,” and the like may be used to distinguish one element from the other, and may not limit a sequence and/or an importance, or others, in relation to the elements. In some cases, a first element may be referred to as a second element, and similarly, a second element may be referred to as a first element without departing from the scope of right of the example embodiments.

In the example embodiments, the term “example embodiment” may not refer to one same example embodiment, and may be provided to describe and emphasize different unique features of each example embodiment. The above suggested example embodiments may be implemented do not exclude the possibilities of combination with features of other example embodiments. For example, even though the features described in one example embodiment are not described in the other example embodiment, the description may be understood as relevant to the other example embodiment unless otherwise indicated.

An expression used in the singular encompasses the expression of the plural, unless it has a clearly different meaning in the context.

While the example embodiments have been illustrated and described above, it will be apparent to those skilled in the art that modifications and variations could be made without departing from the scope of the present invention as defined by the appended claims.

What is claimed is:

1. A semiconductor package, comprising:
a first substrate including a first insulating layer and a first wiring layer disposed on or in the first insulating layer;
a first package disposed on the first substrate, and including a second substrate, a first semiconductor chip disposed on the second substrate, first connection members connecting the second substrate to the first semiconductor chip, and a first SERDES chip embedded in the second substrate;
a second package disposed on the first substrate, and including a third substrate, a second semiconductor chip disposed on the third substrate, second connection members connecting the third substrate to the second semiconductor chip, and a second SERDES chip embedded in the third substrate;
1-1 connection members connecting the first substrate to the first package; and
2-1 connection members connecting the first substrate to the second package,
wherein the number of first connection members is greater than the number of 1-1 connection members, and
wherein the number of second connection members is greater than the number of 2-1 connection members.

2. The semiconductor package of claim 1,
wherein the second substrate includes a second insulating layer, and second wiring layers disposed on or in the second insulating layer, and
wherein a pitch of one of the second wiring layers connected to the first connection members is smaller than a pitch of another of the second wiring layers connected to the 1-1 connection members.

3. The semiconductor package of claim 2,
wherein the third substrate includes a third insulating layer, and third wiring layers disposed on or in the third insulating layer, and
wherein a pitch of one of the third wiring layers connected to the second connection members is smaller than a pitch of another of the third wiring layers connected to the 2-1 connection members.

4. The semiconductor package of claim 1,
wherein the first substrate further includes a 1-1 insulating layer disposed on an uppermost side of the first insulating layer, and
wherein a dissipation factor of the 1-1 insulating layer is smaller than a dissipation factor of the first insulating layer.

5. The semiconductor package of claim 4, wherein the first semiconductor chip is connected to the second semiconductor chip through a wiring layer disposed on or in the 1-1 insulating layer.

6. The semiconductor package of claim 1,
wherein the first SERDES chip includes a serializer chip, and
wherein the second SERDES chip includes a deserializer chip.

7. The semiconductor package of claim 6,
wherein the serializer chip includes first connection pads,
wherein the deserializer chip includes second connection pads,
wherein, in the first connection pads, the number of input connection pads is greater than the number of output connection pads, and
wherein, in the second connection pads, the number of output connection pads is greater than the number of input connection pads.

8. The semiconductor package of claim 1,
wherein the second substrate includes a second insulating layer, a second wiring layer disposed on or in the second insulating layer, and a first cavity penetrating through at least a portion of the second insulating layer, and
wherein the first SERDES chip is disposed in the first cavity and is embedded by the second insulating layer.

9. The semiconductor package of claim 8,
wherein the third substrate includes a third insulating layer, and a third wiring layer disposed on or in the third insulating layer and a second cavity penetrating through at least a portion of the third insulating layer, and
wherein the second SERDES chip is disposed in the second cavity and is embedded by the third insulating layer.

10. The semiconductor package of claim 9,
wherein the second substrate further includes a first adhesive member interposed between the first SERDES chip and a bottom surface of the first cavity, and
wherein the third substrate further includes a second adhesive member interposed between the second SERDES chip and a bottom surface of the second cavity.

11. The semiconductor package of claim 1,
wherein the second substrate includes a first core layer, a second insulating layer disposed on or below the first core layer, a second wiring layer disposed on or in the first core layer or the second insulating layer, and a first cavity penetrating through at least a portion of the first core layer,
wherein the first SERDES chip is disposed in the first cavity, and
wherein the first core layer includes a material different from the second insulating layer.

12. The semiconductor package of claim 11,
wherein the third substrate includes a second core layer, a third insulating layer disposed on or below the second core layer, a third wiring layer disposed on or in the second core layer or the third insulating layer, and a second cavity penetrating through at least a portion of the second core layer,
wherein the second SERDES chip is disposed in the second cavity, and
wherein the second core layer includes a material different from the third insulating layer.

13. The semiconductor package of claim 1,
wherein the second substrate includes a second insulating layer, and a second wiring layer disposed on or in the second insulating layer,
wherein the third substrate includes a third insulating layer, and a third wiring layer disposed on or in the third insulating layer, and
wherein the second insulating layer and the third insulating layer include an organic material.

14. The semiconductor package of claim 1, wherein the first substrate, the second substrate and the third substrate are disposed be spaced apart from each other.

15. A semiconductor package, comprising:
a first substrate comprising a first insulating layer and a first wiring layer disposed on or in the first insulating layer;
a first package disposed on the first substrate, and including a second substrate, a first semiconductor chip disposed on the second substrate, a first connection member connecting the second substrate to the first semiconductor chip, and a first SERDES chip embedded in the second substrate;
a second package disposed on the first substrate, and including a third substrate, a second semiconductor chip disposed on the third substrate, a second connection member connecting the third substrate to the second semiconductor chip, and a second SERDES chip embedded in the third substrate;
a 1-1 connection member connecting the first substrate to the first package; and
a 2-1 connection member connecting the first substrate to the second package,
wherein the first semiconductor chip and the second semiconductor chip are connected to each other by a path passing through the first SERDES chip, the second substrate, the first substrate, the third substrate, and the second SERDES chip.

16. The semiconductor package of claim 15,
wherein the first SERDES chip includes a serializer chip, and
wherein the second SERDES chip includes a deserializer chip.

17. The semiconductor package of claim 16,
wherein the serializer chip includes a circuit configured to convert a parallel signal into a serial signal, and
wherein the deserializer chip includes a circuit configured to convert a serial signal into a parallel signal.

18. The semiconductor package of claim 17,
wherein the number of signal paths output through the serializer chip is less than the number of signal paths output from the first semiconductor chip, and
wherein the number of signal paths input to the deserializer chip is less than the number of signal paths input to the second semiconductor chip.

19. The semiconductor package of claim 15,
wherein the second substrate includes a second insulating layer, a second wiring layer disposed on or in the second insulating layer, and a first cavity penetrating through at least a portion of the second insulating layer, and
wherein the first SERDES chip is disposed in the first cavity and is embedded by the second insulating layer.

20. The semiconductor package of claim 15,
wherein the second substrate includes a first core layer, a second insulating layer disposed on or below the first core layer, a second wiring layer disposed on or in the first core layer or the second insulating layer, and a first cavity penetrating through at least a portion of the first core layer,
wherein the first SERDES chip is disposed in the first cavity, and
wherein the first core layer includes a material different from the second insulating layer.
